(19) United States
(12) Patent Application Publication
(10) Pub. No.: US 2026/0114287 A1
(43) Pub. Date: Apr. 23, 2026

(54) RADIATION-TOLERANT GROUP III-NITRIDE HETEROSTRUCTURE AND METHOD

(71) Applicant: Raytheon Company, Tewksbury, MA (US)

(72) Inventors: Angela Pizzuto, Pine Meadow, CT (US); Caroline Reilly, Chapel Hill, NC (US); Maher B. Tahhan, Tewksbury, MA (US)

(21) Appl. No.: 18/924,759

(22) Filed: Oct. 23, 2024

(51) Int. Cl. H01L 23/552; H01L 29/20; H01L 29/66; H01L 29/778

(52) U.S. Cl. CPC H10W 42/20; H10D 30/015; H10D 30/475; H10D 62/8503

(57) ABSTRACT

A radiation-tolerant Group III-Nitride heterostructure includes a buffer, an ungraded back barrier, a graded back barrier, and at least one upper layer. The ungraded back barrier is formed over the buffer. The graded back barrier is formed over the ungraded back barrier. The at least one upper layer is formed over the graded back barrier. Either a portion of the graded back barrier is configured to function as a channel or the at least one upper layer includes a channel. The channel is configured to include an induced two-dimensional electron gas. The ungraded back barrier and the graded back barrier are configured to direct mobile charges generated outside the channel in a direction away from the channel and toward the buffer.

### TECHNICAL FIELD

This disclosure relates generally to Group III-Nitride devices, such as Group III-Nitride high-electron-mobility transistors. More specifically, this disclosure relates to a radiation-tolerant Group III-Nitride heterostructure and method.

### BACKGROUND

Conventional Group III-Nitride electronic devices, including high-electron-mobility transistors (HEMTs), are susceptible to single-event effects due to radiation. For example, when a device that includes a conventional HEMT is operated in an environment like space, ionizing radiation striking the HEMT generates charges that move around in the HEMT and accumulate in areas in which they do not belong, eventually leading to device failure or temporary disruption.

### SUMMARY

This disclosure relates to a radiation-tolerant Group III-Nitride heterostructure and method.

In a first embodiment, a radiation-tolerant Group III-Nitride heterostructure may include a buffer, an ungraded back barrier formed over the buffer, a graded back barrier formed over the ungraded back barrier, and at least one upper layer formed over the graded back barrier. Either a portion of the graded back barrier is configured to function as a channel or the at least one upper layer includes a channel. The channel is configured to include an induced two-dimensional electron gas (2DEG). The ungraded back barrier and the graded back barrier are configured to direct mobile charges generated outside the channel in a direction away from the channel and toward the buffer.

Any single one or any combination of the following features may be used with the first embodiment. The ungraded back barrier may include aluminum gallium nitride (AlGaN). The graded back barrier may include indium aluminum nitride (InAlN). The ungraded back barrier may include AlₓGa₁₋ₓN where x is between 0.10 and 0.40 and have a thickness of between 40 and 500 angstroms. The graded back barrier may include In_{y}Al_{1-y}N where y decreases in value within a range between 0.10 and 0.70 and have a thickness of between 40 and 500 angstroms. The graded back barrier may include a double-graded back barrier. The double-graded back barrier may include a decreasing graded back barrier and an increasing graded back barrier. The ungraded back barrier may include AlₓGa₁₋ₓN where x is between 0.10 and 0.40 and have a thickness of between 40 and 500 angstroms. The decreasing graded back barrier may include In_{y}Al_{1-y}N where y decreases in value within a range between 0.10 and 0.70 and have a thickness of between 40 and 500 angstroms. The increasing graded back barrier may include In_{z}Al_{1-z}N where z increases in value within a range between 0.10 and 0.70 and have a thickness of between 40 and 500 angstroms. The ungraded back barrier may include a lower ungraded back barrier and an upper ungraded back barrier. The lower ungraded back barrier may include AlₓGa₁₋ₓN where x is between 0.10 and 0.40 and have a thickness of between 40 and 500 angstroms. The upper ungraded back barrier may include GaN and have a thickness of between 40 and 200 angstroms. The graded back barrier may include In_{y}Al_{1-y}N where y increases in value within a range between 0.10 and 0.70 and have a thickness of between 40 and 500 angstroms. The buffer may include a dopant or crystal defects configured to provide a recombination pathway for the mobile charges generated outside the channel. The heterostructure may include a buffer contact coupled to the buffer. The buffer contact may be configured to provide an escape path for the mobile charges generated outside the channel.

In a second embodiment, a high-electron-mobility transistor (HEMT) may include a substrate, a radiation-tolerant Group III-Nitride heterostructure, a source contact, a drain contact, and a gate contact. The heterostructure may be formed over the substrate and may include at least one upper layer and an ungraded/graded back barrier. Either a portion of the ungraded/graded back barrier is configured to function as a channel or the at least one upper layer includes a channel. The channel is configured to include an induced 2DEG. The ungraded/graded back barrier is configured to direct mobile charges generated outside the channel in a direction away from the channel and toward the substrate. The source contact, the drain contact, and the gate contact may be formed over the ungraded/graded back barrier.

Any single one or any combination of the following features may be used with the second embodiment. The ungraded/graded back barrier may include an ungraded back barrier formed over the substrate and a graded back barrier formed over the ungraded back barrier. The ungraded back barrier may include AlGaN. The graded back barrier may include InAlN. The ungraded back barrier may include AlₓGa₁₋ₓN where x is between 0.10 and 0.40 and have a thickness of between 40 and 500 angstroms. The graded back barrier may include In_{y}Al_{1-y}N where y decreases in value within a range between 0.10 and 0.70 and have a thickness of between 40 and 500 angstroms. The graded back barrier may include a double-graded back barrier. The double-graded back barrier may include a decreasing graded back barrier and an increasing graded back barrier. The ungraded back barrier may include AlₓGa₁₋ₓN where x is between 0.10 and 0.40 and have a thickness of between 40 and 500 angstroms. The decreasing graded back barrier may include In_{y}Al_{1-y}N where y decreases in value within a range between 0.10 and 0.70 and have a thickness of between 40 and 500 angstroms. The increasing graded back barrier may include In_{z}Al_{1-z}N where z increases in value within a range between 0.10 and 0.70 and have a thickness of between 40 and 500 angstroms. The ungraded back barrier may include a lower ungraded back barrier and an upper ungraded back barrier. The lower ungraded back barrier may include AlₓGa₁₋ₓN where x is between 0.10 and 0.40 and have a thickness of between 40 and 500 angstroms. The upper ungraded back barrier may include GaN and have a thickness of between 40 and 200 angstroms. The graded back barrier may include In_{y}Al_{1-y}N where y increases in value within a range between 0.10 and 0.70 and have a thickness of between 40 and 500 angstroms. The HEMT may include a substrate contact coupled to the substrate. The substrate contact may be configured to provide an escape path for the mobile charges generated outside the channel.

In a third embodiment, a method may include forming a buffer, forming an ungraded back barrier over the buffer, forming a graded back barrier over the ungraded back barrier, and forming at least one upper layer over the graded back barrier. Either a portion of the graded back barrier is configured to function as a channel or the at least one upper layer comprises a channel. The channel is configured to include an induced 2DEG. The ungraded back barrier and the graded back barrier are configured to direct mobile charges generated outside the channel in a direction away from the channel and toward the buffer.

Any single one or any combination of the following features may be used with the third embodiment. Forming the graded back barrier over the ungraded back barrier may include forming a decreasing graded back barrier over the ungraded back barrier and forming an increasing graded back barrier over the decreasing graded back barrier. Forming the ungraded back barrier over the buffer may include forming a lower ungraded back barrier over the buffer and forming an upper ungraded back barrier over the lower ungraded back barrier.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example of a radiation-tolerant Group III-Nitride heterostructure according to this disclosure;

FIGS. 2A-C illustrate examples of embodiments of the radiation-tolerant Group III-Nitride heterostructure of FIG. 1 according to this disclosure;

FIGS. 3A-D illustrate a set of graphs depicting examples of band diagrams and corresponding free carrier distribution associated with embodiments of a radiation-tolerant Group III-Nitride heterostructure according to this disclosure;

FIG. 4 illustrates an example of a high-electron-mobility transistor (HEMT) including a radiation-tolerant Group III-Nitride heterostructure according to this disclosure;

FIGS. 5A-C illustrate examples of managing mobile charges redirected by a radiation-tolerant Group III-Nitride heterostructure according to this disclosure;

FIGS. 6A-B illustrate a set of graphs depicting examples of charge movement related to the use of a radiation-tolerant Group III-Nitride heterostructure in the HEMT of FIG. 4 according to this disclosure; and

FIG. 7 illustrates an example of a method for fabricating a radiation-tolerant Group III-Nitride heterostructure according to this disclosure.

### DETAILED DESCRIPTION

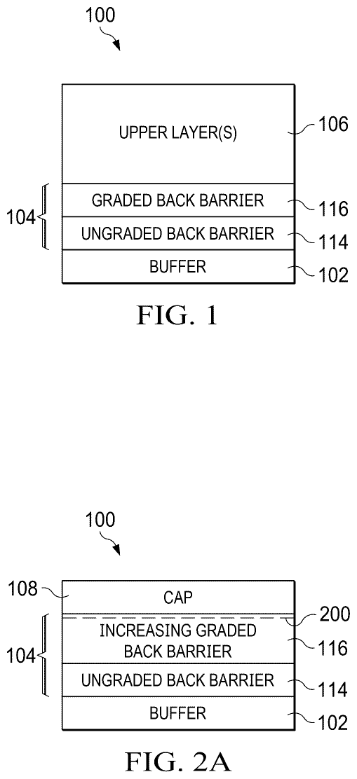

FIGS. 1 through 7, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, conventional Group III-Nitride high-electron-mobility transistors (HEMTs) are highly susceptible to single-event effects (SEEs) due to radiation. For example, when a device that includes a conventional HEMT is operated in an environment like space, ionizing radiation striking the HEMT generates charges that move around in the HEMT and accumulate in areas in which they do not belong, eventually leading to device failure. To deal with this issue, one approach has included designing apparatuses without the use of transistors, which can cause design difficulties and increase the complexity of the resulting apparatuses. Another approach has included trapping and recombining electron-hole pairs generated by the ionizing radiation in quantum well layers that have smaller band gaps as compared to barrier layers of the device.

This disclosure provides a radiation-tolerant Group III-Nitride heterostructure and method. As described in more detail below, a radiation-tolerant Group III-Nitride heterostructure can include a buffer, an ungraded back barrier, a graded back barrier, and at least one upper layer. The ungraded back barrier can be formed over the buffer. The graded back barrier can be formed over the ungraded back barrier. The at least one upper layer can be formed over the graded back barrier. Either a portion of the graded back barrier is configured to function as a channel or the at least one upper layer includes a channel. In some cases, the ungraded back barrier can include a lower ungraded back barrier and an upper ungraded back barrier. In other cases, the graded back barrier can include a decreasing graded back barrier and an increasing graded back barrier. The ungraded back barrier and the graded back barrier can be configured to direct mobile charges generated by radiation in a direction away from the channel and toward the buffer. In this way, an energetic barrier can be created so that extraneous charge is directed away from the two-dimensional electron gas (2DEG), preventing a charge build-up in the region that can cause damage to the device.

FIG. 1 illustrates an example of a radiation-tolerant Group III-Nitride heterostructure 100 according to this disclosure. The embodiment of the heterostructure 100 shown in FIG. 1 is for illustration only. Other embodiments of the heterostructure 100 may be used without departing from the scope of this disclosure.

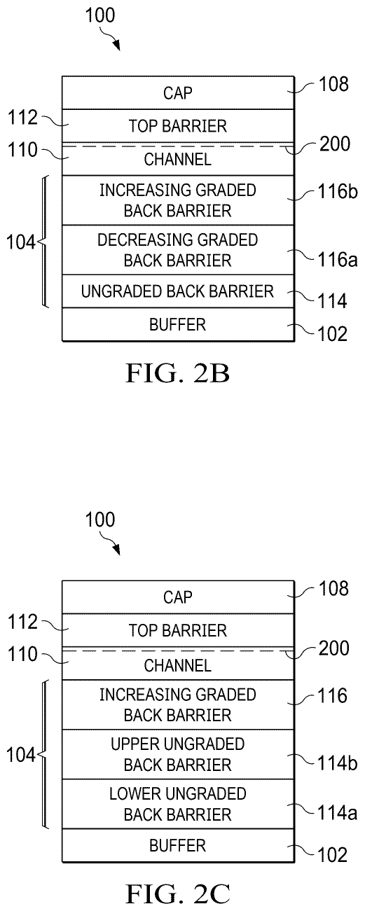

According to embodiments of this disclosure, the heterostructure 100 may include a buffer 102, an ungraded/graded (U/G) back barrier 104 formed over the buffer 102, and one or more upper layers 106 formed over the U/G back barrier 104. As described below in connection with FIGS. 2A-2C, the upper layers 106 may include a channel, a top barrier and/or a cap 108.

As described in more detail below, the U/G back barrier 104 includes an ungraded back barrier 114 and a graded back barrier 116. As used here, an “ungraded” barrier means that the barrier includes a material whose composition remains substantially the same throughout the barrier. Note that, in some embodiments, the ungraded back barrier 114 may include multiple layers, each of which may include a material whose composition remains substantially the same throughout the layer. Similarly, as used here, a “graded” barrier means that the barrier includes at least two materials whose compositions transition from one concentration to at least one different concentration, possibly substantially continuously. Note that, in some embodiments, the compositions may transition to multiple different concentrations, such as by a material first increasing in concentration and then decreasing in concentration or vice versa.

The U/G back barrier 104 is configured to direct charges generated by SEEs away from a sensitive region of the heterostructure 100. As used here, the “sensitive region” of the heterostructure 100 means a region in which intrinsic free carriers may exist while a device including the heterostructure 100 is operating. For example, for embodiments in which the heterostructure 100 is implemented in a HEMT, the sensitive region may include a channel or other region in which a 2DEG may be induced. Thus, while intrinsic free carriers in the sensitive region are desirable and useful during operation, extraneous free carriers in the sensitive region that are generated by SEEs can result in device malfunction or failure.

When the heterostructure 100 is exposed to radiation, SEEs may result in mobile charges being generated in a portion of the heterostructure 100 that is below the sensitive region. The U/G back barrier 104 may be configured to reduce or prevent these generated charges from moving toward the surface of the heterostructure 100 and entering the sensitive region and may be configured to instead direct the charges in the opposite direction away from the sensitive region. For example, the U/G back barrier 104 may be incorporated into the layer structure with properties that form an energetic barrier near the 2DEG, such that resulting electric fields pull ion-induced free carriers away from the sensitive region. In this way, charges generated due to SEEs may be prevented from entering, accumulating in, and damaging the sensitive region of the heterostructure 100.

In some embodiments, the buffer 102 may include n-type gallium nitride (GaN), the ungraded back barrier 114 may include aluminum gallium nitride (AlGaN), the graded back barrier 116 may include indium aluminum nitride (InAlN), the channel 110 may include GaN, the top barrier 112 may include AlGaN, and the cap 108 may include p-type GaN. Also, in some embodiments, the ungraded back barrier 114 includes AlₓGa₁₋ₓN, where x is a concentration of aluminum and 1-x is a concentration of gallium. Also, in some embodiments, the graded back barrier 116 includes In_{y1}Al_{1-y1}N to In_{y2}Al_{1-y2}N such that the concentrations of indium and aluminum transition to different concentrations from the bottom of the graded back barrier 116 to the top of the graded back barrier 116, where y1 is a concentration of indium at the bottom and y2 is a concentration of indium at the top and where 1 -y1 is a concentration of aluminum at the bottom and 1-y2 is a concentration of aluminum at the top. In addition, in some embodiments, the top barrier 112 includes Al_{z}Ga_{1-z}N, where z is a concentration of aluminum and 1-z is a concentration of gallium.

In particular embodiments, the buffer 102 may include n-type doped GaN with a concentration of about 10¹⁵ to about 10¹⁷/cm³ and a thickness of about 1,000 angstroms, the ungraded back barrier 114 may include AlₓGa₁₋ₓN where x is between 0.10 and 0.40 and have a thickness of between 40 and 500 angstroms, the graded back barrier 116 may include In_{y}Al_{1-y}N where y increases in value within a range between 0.10 and 0.70 and have a thickness of between 40 and 500 angstroms, the channel 110 may include GaN and have a thickness of between 40 and 500 angstroms, the top barrier 112 may include Al_{z}Ga_{1-z}N where z is between 0.20 and 0.35 and have a thickness of between 40 and 500 angstroms, and the cap 108 may include p-type doped GaN with a concentration of about 10¹⁵ to about 10¹⁷/cm³ and a thickness of between 40 and 500 angstroms.

Although FIG. 1 illustrates one example of a radiation-tolerant Group III-Nitride heterostructure 100, various changes may be made to FIG. 1. For instance, the heterostructure 100 may include additional layers not shown in FIG. 1. Also, the illustrated layers of the heterostructure 100 may include any suitable Group III-Nitride materials other than those described above or include materials having different concentrations, doping, polarity and/or thicknesses from those described above. In particular, the graded back barrier 116 may include In_{y}Al_{1-y}N where y changes in value within a range between 0 and 1, a range between 0.20 and 0.55, or any other suitable range. In addition, note that the view shown in FIG. 1 is not to scale.

FIGS. 2A-C illustrate examples of embodiments of the radiation-tolerant Group III-Nitride heterostructure 100 according to this disclosure. The embodiments of the heterostructures 100 shown in FIGS. 2A-C are for illustration only. Other embodiments of the heterostructure 100 may be used without departing from the scope of this disclosure.

According to embodiments of this disclosure, as illustrated in FIG. 2A, the heterostructure 100 may include the buffer 102, the U/G back barrier 104 formed over the buffer 102, and a cap 108 formed over the U/G back barrier 104. Thus, for this embodiment, the upper layer 106 includes the cap 108. The U/G back barrier 104 includes the ungraded back barrier 114 and the graded back barrier 116. Thus, the ungraded back barrier 114 may be formed over the buffer 102, and the graded back barrier 116 may be formed over the ungraded back barrier 114. A 2DEG 200 may be induced in the graded back barrier 116 such that a portion of the graded back barrier 116 is configured to function as a channel.

In some embodiments, the buffer 102 may include n-type GaN, the ungraded back barrier 114 may include AlGaN, the graded back barrier 116 may include InAlN, and the cap 108 may include p-type GaN. For the illustrated embodiment, the graded back barrier 116 includes an increasing graded back barrier 116. For example, the concentration of aluminum in the increasing graded back barrier 116 may transition from a lower concentration to a higher concentration from the bottom of the increasing graded back barrier 116 (on the side closer to the ungraded back barrier 114) to the top of the increasing graded back barrier 116 (on the side farther away from the ungraded back barrier 114). Similarly, the concentration of indium in the increasing graded back barrier 116 may transition from a higher concentration to a lower concentration from the bottom of the increasing graded back barrier 116 to the top of the increasing graded back barrier 116.

In particular embodiments, the buffer 102 may include n-type doped GaN with a concentration of about 10¹⁵ to about 10¹⁷/cm³ and a thickness of about 1,000 angstroms, the ungraded back barrier 114 may include AlₓGa₁₋ₓN where x is between 0.10 and 0.40 and have a thickness of between 40 and 500 angstroms, the increasing graded back barrier 116 may include In_{y}Al_{1-y}N where y decreases in value within a range between 0.10 and 0.70 and have a thickness of between 40 and 500 angstroms, and the cap 108 may include p-type doped GaN with a concentration of about 10¹⁵ to about 10¹⁷/cm³ and a thickness of between 40 and 500 angstroms.

According to embodiments of this disclosure, as illustrated in FIG. 2B, the heterostructure 100 may include the buffer 102, the U/G back barrier 104 formed over the buffer 102, a channel 110 formed over the U/G back barrier 104, a top barrier 112 formed over the channel 110, and the cap 108 formed over the top barrier 112. Thus, for this embodiment, the upper layers 106 include the channel 110, the top barrier 112, and the cap 108.

The U/G back barrier 104 includes the ungraded back barrier 114 and the graded back barrier 116. In addition, the graded back barrier 116 includes a double-graded back barrier 116. This double-graded back barrier 116 includes a decreasing graded back barrier 116a and an increasing graded back barrier 116b. Thus, the ungraded back barrier 114 may be formed over the buffer 102, the decreasing graded back barrier 116a may be formed over the ungraded back barrier 114, and the increasing graded back barrier 116b may be formed over the decreasing graded back barrier 116a. The heterostructure 100 may also include a 2DEG 200 induced in the channel 110.

In some embodiments, the buffer 102 may include n-type GaN, the ungraded back barrier 114 may include AlGaN, the double-graded back barrier 116 may include InAlN, the channel 110 may include GaN, the top barrier 112 may include AlGaN, and the cap 108 may include p-type GaN.

In particular embodiments, the buffer 102 may include n-type doped GaN with a concentration of about 10¹⁵ to about 10¹⁷/cm³ and a thickness of about 1,000 angstroms, the ungraded back barrier 114 may include AlₓGa₁₋ₓN where x is between 0.10 and 0.40 and have a thickness of between 40 and 500 angstroms, the decreasing graded back barrier 116a may include In_{y}Al_{1-y}N where y decreases in value within a range between 0.10 and 0.70 and have a thickness of between 40 and 500 angstroms, the increasing graded back barrier 116b may include In_{z}Al_{1-z}N where z increases in value within a range between 0.10 and 0.70 and have a thickness of between 40 and 500 angstroms, the channel 110 may include GaN and have a thickness of between 40 and 200 angstroms, the top barrier 112 may include AlₙGa₁₋ₙN where n is between 0.20 and 0.35 and have a thickness of between 40 and 500 angstroms, and the cap 108 may include p-type doped GaN with a concentration of about 10¹⁵ to about 10¹⁷/cm³ and a thickness of between 40 and 500 angstroms.

According to embodiments of this disclosure, as illustrated in FIG. 2C, the heterostructure 100 may include the buffer 102, the U/G back barrier 104 formed over the buffer 102, the channel 110 formed over the U/G back barrier 104, the top barrier 112 formed over the channel 110, and the cap 108 formed over the top barrier 112. Thus, for this embodiment, the upper layers 106 include the channel 110, the top barrier 112, and the cap 108.

The U/G back barrier 104 includes the ungraded back barrier 114 and the graded back barrier 116. For the illustrated embodiment, the ungraded back barrier 114 includes a lower ungraded back barrier 114a and an upper ungraded back barrier 114b. In addition, the graded back barrier 116 includes an increasing graded back barrier 116. Thus, the lower ungraded back barrier 114a may be formed over the buffer 102, the upper ungraded back barrier 114b may be formed over the lower ungraded back barrier 114a, and the graded back barrier 116 may be formed over the upper ungraded back barrier 114b. The heterostructure 100 may also include a 2DEG 200 induced in the channel 110.

In some embodiments, the buffer 102 may include n-type GaN, the lower ungraded back barrier 114a may include AlGaN, the upper ungraded back barrier 114b may include GaN, the graded back barrier 116 may include InAlN, the channel 110 may include GaN, the top barrier 112 may include AlGaN, and the cap 108 may include p-type GaN.

In particular embodiments, the buffer 102 may include n-type doped GaN with a concentration of about 10¹⁵ to about 10¹⁷/cm³ and a thickness of about 1,000 angstroms, the lower ungraded back barrier 114a may include AlₓGa₁₋ₓN where x is between 0.10 and 0.40 and have a thickness of between 40 and 500 angstroms, the upper ungraded back barrier 114b may include GaN and have a thickness of between 40 and 200 angstroms, the increasing graded back barrier 116 may include In_{y}Al_{1-y}N where y increases in value within a range between 0.10 and 0.70 and have a thickness of between 40 and 500 angstroms, the channel 110 may include GaN and have a thickness of between 40 and 500 angstroms, the top barrier 112 may include Al_{z}Ga_{1-z}N where z is between 0.10 and 0.40 and have a thickness of between 40 and 500 angstroms, and the cap 108 may include p-type doped GaN with a concentration of about 10¹⁵ to about 10¹⁷/cm³ and a thickness of between 40 and 500 angstroms.

Although FIGS. 2A-C illustrate some examples of a radiation-tolerant Group III-Nitride heterostructure 100, various changes may be made to FIGS. 2A-C. For instance, the illustrated heterostructures 100 may include additional layers not shown in FIGS. 2A-C. Also, the illustrated layers of the heterostructures 100 may include any suitable Group III-Nitride materials other than those described above or include materials having different concentrations, doping, polarity and/or thicknesses from those described above. In particular, the graded back barrier 116, 116a or 116b may include In_{y}Al_{1-y}N where y changes in value within a range between 0 and 1, a range between 0.20 and 0.55, or any other suitable range. In addition, note that the views shown in FIGS. 2A-C are not to scale.

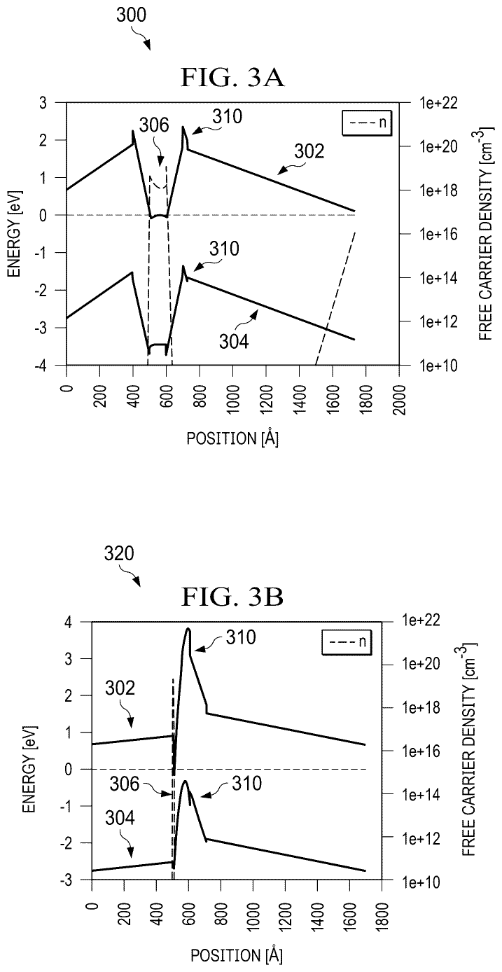

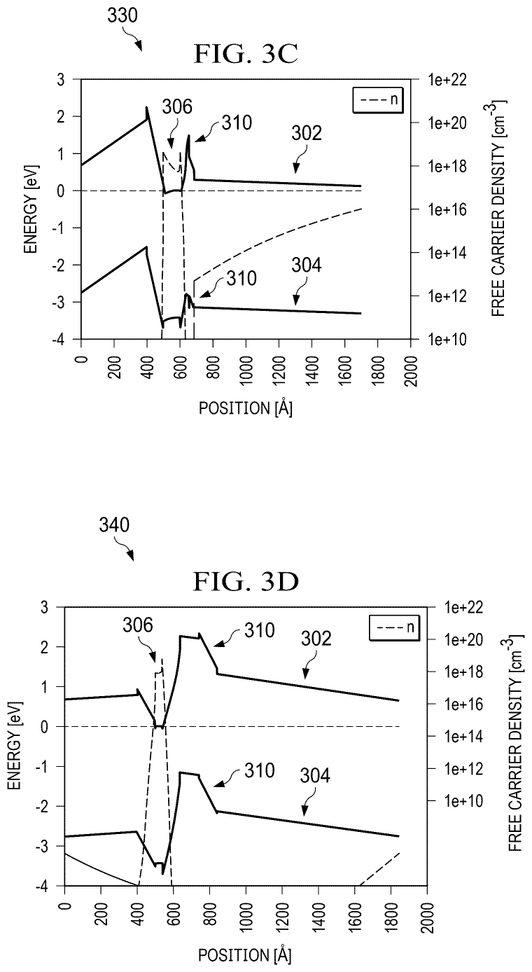

FIGS. 3A-D illustrate a set of graphs depicting examples of band diagrams and corresponding free carrier distribution associated with embodiments of a radiation-tolerant Group III-Nitride heterostructure 100 according to this disclosure. The graphs shown in FIGS. 3A-D are for illustration only.

FIG. 3A illustrates a graph 300 of one example of band diagrams and corresponding free carrier distribution for the heterostructure 100 of FIG. 1, where the upper layers 106 of the heterostructure 100 include the channel 110, the top barrier 112, and the cap 108. FIG. 3B illustrates a graph 320 of one example of band diagrams and corresponding free carrier distribution for the heterostructure 100 of FIG. 2A. FIG. 3C illustrates a graph 330 of one example of band diagrams and corresponding free carrier distribution for the heterostructure 100 of FIG. 2B. FIG. 3D illustrates a graph 340 of one example of band diagrams and corresponding free carrier distribution for the heterostructure 100 of FIG. 2C.

Each of the graphs 300, 320, 330, and 340 shown in FIGS. 3A-D illustrates the energy potential in electron-volts relative to position in angstroms from the surface of the corresponding heterostructure 100. Thus, the energy potential at the surface is plotted where x=0 angstroms, with the energy potential deeper into the heterostructure 100 plotted along the x-axis with increasing position values. Likewise, the free carrier distribution is shown relative to the depth position within the corresponding heterostructure 100.

The graphs 300, 320, 330, and 340 include the energy potential for a conduction band 302 and a valence band 304, along with corresponding intrinsic free carrier distribution 306. The conduction band 302 and valence band 304 each include an energy potential barrier 310 that results from the U/G back barrier 104 of the heterostructure 100. These energy potential barriers 310 are incorporated into the layer structure with properties that form an energetic barrier near the 2DEG, such that resulting electric fields pull ion-induced free carriers away from the channel. In this way, extraneous free carriers are prevented from entering the sensitive region of the heterostructure 100, which is closer to the surface, and instead direct those free carriers deeper into the heterostructure 100 toward the buffer 102 and beyond. For embodiments including the channel 110, the sensitive region includes the channel 110. For embodiments in which a portion of the graded back barrier 116 is configured to function as a channel, the sensitive region includes the graded back barrier 116. The band structure directs the extraneous free charges toward the buffer 102 because the electric field in the U/G back barrier 104 is configured to apply an electric force on charges located below the sensitive region such that they do not enter the sensitive region. Intrinsic free carriers that are desirable and useful for operation of the heterostructure 100 are able to move within the sensitive region, while extraneous free carriers are directed away from the sensitive region.

Although FIGS. 3A-D illustrate some examples of band diagrams and corresponding free carrier distribution associated with a radiation-tolerant Group III-Nitride heterostructure 100, various changes may be made to FIGS. 3A-D. For instance, the energy potentials of the conduction bands 302 and valence bands 304, along with the actual corresponding intrinsic free carrier distributions 306, may vary with design and performance during operation of a device including the heterostructure 100 and based on SEEs occurring as a result of radiation, which are unpredictable. However, it will be understood that similar bands 302 and 304 and free carrier distributions 306 can occur as a result of the implementations of the heterostructures 100 of FIGS. 1 and 2A-2C, which are configured to provide energy potential barriers 310 through the inclusion of the U/G back barrier 104.

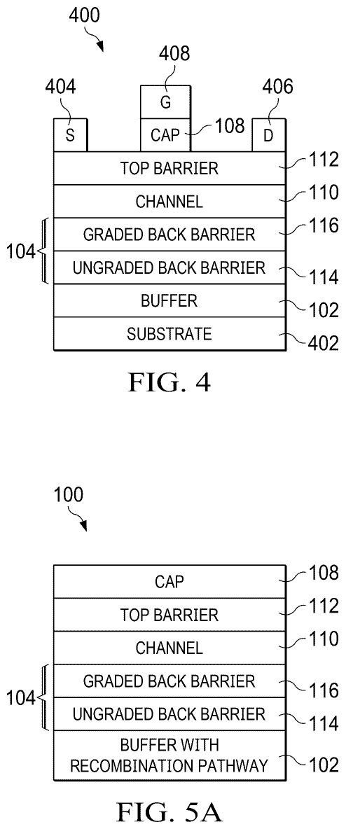

FIG. 4 illustrates an example of a HEMT 400 including a radiation-tolerant Group III-Nitride heterostructure 100 according to this disclosure. The embodiment of the HEMT 400 shown in FIG. 4 is for illustration only. Other embodiments of the HEMT 400 may be used without departing from the scope of this disclosure.

According to embodiments of this disclosure, the HEMT 400 may include a substrate 402, a heterostructure 100, a source contact(S) 404, a drain contact (D) 406, and a gate contact (G) 408. The substrate 402 may include silicon, silicon carbide, sapphire, GaN, diamond, AlN, or any other suitable substrate material. The source contact 404 and the drain contact 406 may be formed over the top barrier 112 of the heterostructure 100, as illustrated. For alternative embodiments, the source contact 404 and the drain contact 406 may be formed over the U/G back barrier 104 or over the channel 110. The gate contact 408 may be formed over the cap 108, as illustrated. For alternative embodiments, the gate contact 408 may be formed over the channel 110 or over the top barrier 112. In some embodiments, the heterostructure 100 may include one of the heterostructures 100 described above in connection with FIG. 1 or 2A-2C or other heterostructure designed in accordance with this disclosure. Thus, the ungraded back barrier 114 and the graded back barrier 116 may each include one or more layers as described above.

By including the heterostructure 100 in the HEMT 400, the U/G back barrier 104 of the heterostructure 100 is able to provide radiation tolerance for the HEMT 400, protecting the HEMT 400 from many of the harmful effects of radiation as described above. The heterostructure 100 is configured to direct mobile charges generated outside the channel 110 away from the channel 110 and toward the substrate 402. In this way, the HEMT 400 is protected from accumulation of mobile charges in the sensitive region of the HEMT 400, which can cause the HEMT 400 to malfunction or fail. This allows the use of HEMTs 400 in environments such as space where radiation can cause extensive damage to a conventional HEMT.

Although FIG. 4 illustrates one example of a HEMT 400 including a radiation-tolerant Group III-Nitride heterostructure 100, various changes may be made to FIG. 4. For instance, the HEMT 400 may include additional components not shown in FIG. 4. Also, note that the channel 110 and the top barrier 112 are optional layers of the heterostructure 100 and may be omitted, and the U/G back barrier 104 may include a multi-layered ungraded back barrier 114 or a multi-layered graded back barrier 116 as described above. In addition, note that the view shown in FIG. 4 is not to scale.

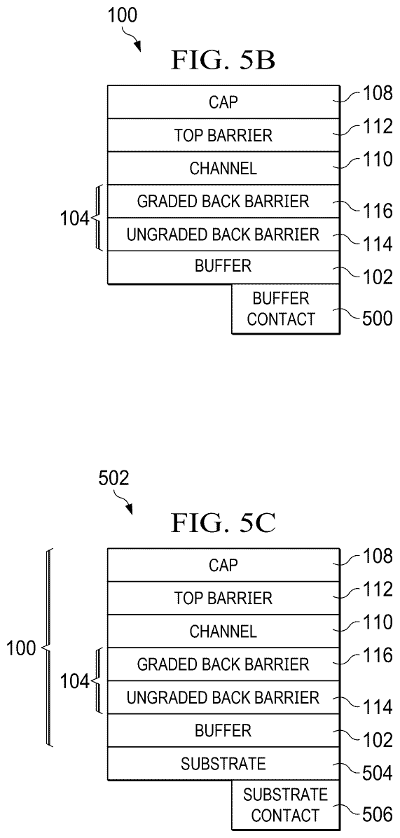

FIGS. 5A-C illustrate examples of managing mobile charges redirected by a radiation-tolerant Group III-Nitride heterostructure 100 according to this disclosure. The embodiments of the heterostructures 100 shown in FIGS. 5A-C are for illustration only. Other embodiments of the heterostructure 100 may be used without departing from the scope of this disclosure.

According to embodiments of this disclosure, as illustrated in FIG. 5A, the buffer 102 of the heterostructure 100 may include a buffer with a recombination pathway for mobile charges that may be generated outside the channel 110 by radiation. In some embodiments, the recombination pathway may be provided as part of the buffer 102 through the inclusion of a dopant in the buffer 102. In other embodiments, the recombination pathway may be provided as part of the buffer 102 through the inclusion of crystal defects in the buffer 102.

According to embodiments of this disclosure, as illustrated in FIG. 5B, the heterostructure 100 may include a buffer contact 500 coupled to the buffer 102. The buffer contact 500 is configured to provide an escape path for mobile charges. The buffer contact 500 may include any suitable conductive material through which charges are free to move. Thus, the buffer contact 500 may provide a path for the mobile charges, which have been directed away from the channel 110 and toward the buffer 102, to leave the heterostructure 100.

As illustrated in FIG. 5C, according to embodiments of this disclosure in which the heterostructure 100 is included as part of a device such as a HEMT 502, the HEMT 502 may include a substrate 504 and a substrate contact 506 coupled to the substrate 504. Similar to the buffer contact 500 of FIG. 5B, the substrate contact 506 is configured to provide an escape path for mobile charges. The substrate contact 506 may include any suitable conductive material through which charges are free to move. Thus, the substrate contact 506 may provide a path for the mobile charges, which have been directed away from the channel 110 and toward the substrate 504, to leave the HEMT 502.

Although FIGS. 5A-C illustrate some examples of managing mobile charges redirected by a radiation-tolerant Group III-Nitride heterostructure 100, various changes may be made to FIGS. 5A-C. For instance, the ungraded back barrier 114 and the graded back barrier 116 may each include multiple layers, such as described above in connection with FIGS. 2B and 2C. In addition, the heterostructures 100 of FIGS. 5A-C may be implemented without the channel 110 and/or the top barrier 112. Also, the heterostructures 100 may include additional components not shown in FIGS. 5A-C. In addition, note that the views shown in FIGS. 5A-C are not to scale.

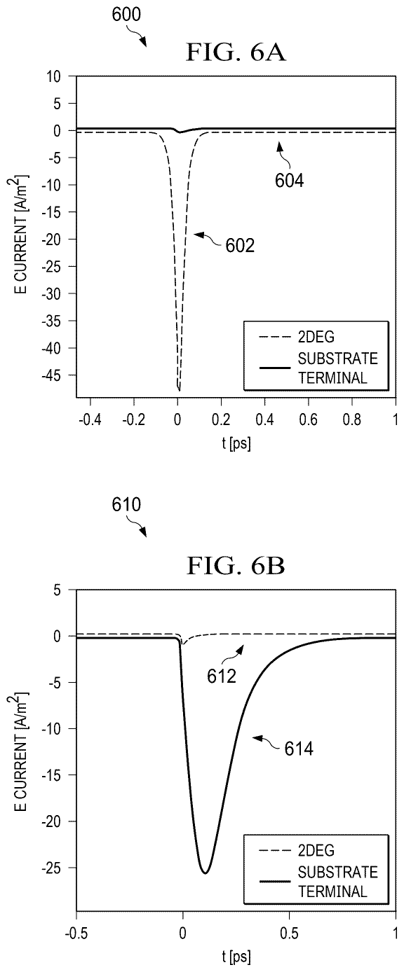

FIGS. 6A-B illustrate a set of graphs 600 and 610 depicting examples of charge movement related to the use of a radiation-tolerant Group III-Nitride heterostructure 100 in a HEMT 400 according to this disclosure. The charge movements shown in FIGS. 6A-B are for illustration only. Different movement of charges may occur based on different embodiments of the heterostructure 100 without departing from the scope of this disclosure.

According to embodiments of this disclosure, the charge movement as a function of time that is shown in the graph 600 of FIG. 6A includes a relatively large amount of current 602 generated in the 2DEG 200 as compared to a very small amount of current 604 generated in the substrate 402 without the inclusion of the heterostructure 100 in the HEMT 400. On the other hand, the charge movement as a function of time that is shown in the graph 610 of FIG. 6B includes a very small amount of current 612 generated in the 2DEG 200 as compared to a relatively large amount of current 614 generated in the substrate 402 when the heterostructure 100 is included in the HEMT 400.

Thus, including the heterostructure 100 as part of the HEMT 400 results in mobile charges being moved toward the substrate 402 and away from the channel 110 of the HEMT 400, which can include an induced 2DEG 200, thereby protecting the HEMT 400 from the accumulation of charges in the channel 110 and subsequent damage to, and malfunction of, the HEMT 400 when in the presence of ionizing radiation.

Although FIGS. 6A-B illustrate some examples of charge movement related to the use of a radiation-tolerant Group III-Nitride heterostructure 100, various changes may be made to FIGS. 6A-B. For instance, the charge movement over time will vary with performance during operation of a device, such as the HEMT 400, that includes the heterostructure 100 and based on SEEs occurring as a result of radiation, which are unpredictable. However, it will be understood that charge movement similar to that shown in the graph 600 will result from the use of a conventional Group III-nitride HEMT heterostructure, and charge movement similar to that shown in the graph 610 will result when the heterostructure 100 is implemented due to the heterostructure 100 being configured to redirect mobile charges away from the 2DEG 200 and toward the substrate 402 through the inclusion of the U/G back barrier 104.

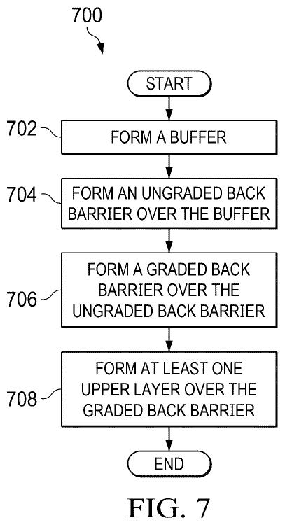

FIG. 7 illustrates an example of a method 700 for fabricating a radiation-tolerant Group III-Nitride heterostructure 100 according to this disclosure. For ease of explanation, the method 700 is described as being used to form the heterostructure 100 shown in FIG. 1. However, the method 700 may be used to form any other suitable heterostructure 100 designed in accordance with this disclosure.

As shown in FIG. 7, a buffer 102 is formed at step 702. This may include, for example, depositing the buffer 102 over a substrate 402 or 504 of a device such as a HEMT 400 or 502. In some embodiments, the buffer 102 may include GaN. In particular embodiments, the buffer 102 may include n-type doped GaN with a concentration of about 10¹⁵ to about 10¹⁷/cm³ and may have a thickness of about 1,000 angstroms.

An ungraded back barrier 114 is formed over the buffer 102 at step 704. In some embodiments, the ungraded back barrier 114 may include AlGaN. In particular embodiments, the ungraded back barrier 114 may include AlₓGa₁₋ₓN where x is between 0.10 and 0.40 and have a thickness of between 40 and 500 angstroms. In other particular embodiments, the ungraded back barrier 114 may include AlₓGa₁₋ₓN where x is between 0.10 and 0.40 and have a thickness of between 40 and 500 angstroms. In other embodiments, the ungraded back barrier 114 may include a lower ungraded back barrier 114a and an upper ungraded back barrier 114b. For some of these embodiments, the lower ungraded back barrier 114a may include AlGaN, and the upper ungraded back barrier 114b may include GaN. In particular embodiments, the lower ungraded back barrier 114a may include AlₓGa₁₋ₓN where x is between 0.10 and 0.40 and have a thickness of between 40 and 500 angstroms, and the upper ungraded back barrier 114b may include GaN and have a thickness of between 40 and 200 angstroms.

A graded back barrier 116 is formed over the ungraded back barrier 114 at step 706. In some embodiments, the graded back barrier 116 may include InAlN. In particular embodiments, the graded back barrier 116 may include In_{y}Al_{1-y}N where y decreases in value within a range between 0.10 and 0.70 and have a thickness of between 40 and 500 angstroms. In other particular embodiments, the graded back barrier 116 may include In_{y}Al_{1-y}N where y increases in value within a range between 0.10 and 0.70 and have a thickness of between 40 and 500 angstroms. In other embodiments, the graded back barrier 116 may include a decreasing graded back barrier 116a and an increasing graded back barrier 116b. In particular embodiments, the decreasing graded back barrier 116a may include In_{y}Al_{1-y}N where y decreases in value within a range between 0.10 and 0.70 and have a thickness of between 40 and 500 angstroms, and the increasing graded back barrier 116b may include In_{z}Al_{1-z}N where z increases in value within a range between 0.10 and 0.70 and have a thickness of between 40 and 500 angstroms. Note that the graded back barrier 116 may include In_{y}Al_{1-y}N where y changes in value within a range between 0 and 1, a range between 0.20 and 0.55, or any other suitable range.

At least one upper layer 106 may be formed over the graded back barrier 116 at step 708. The at least one upper layer 106 may include a channel 110, a top barrier 112 and/or a cap 108. In some embodiments, the channel 110 may include GaN. In particular embodiments, the channel 110 may have a thickness of between 40 and 500 angstroms. In some embodiments, the top barrier 112 may include AlGaN. In particular embodiments, the top barrier 112 may include AlₙGa₁₋ₙN where n is between 0.20 and 0.35 and have a thickness of between 40 and 500 angstroms. In other particular embodiments, the top barrier 112 may include AlₙGa₁₋ₙN where n is between 0.10 and 0.40 and have a thickness of between 40 and 500 angstroms. In some embodiments, the cap 108 may include GaN. In particular embodiments, the cap 108 may include p-type doped GaN with a concentration of about 10¹⁵ to about 10¹⁷/cm³ and may have a thickness of between 40 and 500 angstroms.

Although FIG. 7 illustrates one example of a method 700 for fabricating a radiation-tolerant Group III-Nitride heterostructure 100, various changes may be made to FIG. 7. For example, while shown as a series of steps, various steps in FIG. 7 may overlap, occur in parallel, occur in a different order, or occur any number of times (including zero times).

It may be advantageous to set forth definitions of certain words and phrases used throughout this patent document. The term “about” (when used with a numerical value) indicates that the numerical value may vary by up to ±10%. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S. C. § 114(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S. C. § 114(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A radiation-tolerant Group III-Nitride heterostructure comprising:
a buffer;
an ungraded back barrier formed over the buffer;
a graded back barrier formed over the ungraded back barrier; and
at least one upper layer formed over the graded back barrier;
wherein either a portion of the graded back barrier is configured to function as a channel or the at least one upper layer comprises a channel;
wherein the channel is configured to comprise an induced two-dimensional electron gas (2DEG); and
wherein the ungraded back barrier and the graded back barrier are configured to direct mobile charges generated outside the channel in a direction away from the channel and toward the buffer.

2. The heterostructure of claim 1, wherein:
the ungraded back barrier comprises aluminum gallium nitride (AlGaN); and
the graded back barrier comprises indium aluminum nitride (InAlN).

3. The heterostructure of claim 1, wherein:
the ungraded back barrier comprises AlₓGa₁₋ₓN where x is between 0.10 and 0.40 and has a thickness of between 40 and 500 angstroms; and
the graded back barrier comprises In_{y}Al_{1-y}N where y decreases in value within a range between 0.10 and 0.70 and has a thickness of between 40 and 500 angstroms.

4. The heterostructure of claim 1, wherein the graded back barrier comprises a double-graded back barrier.

5. The heterostructure of claim 4, wherein:
the double-graded back barrier comprises a decreasing graded back barrier and an increasing graded back barrier;
the ungraded back barrier comprises AlₓGa₁₋ₓN where x is between 0.10 and 0.40 and has a thickness of between 40 and 500 angstroms;
the decreasing graded back barrier comprises In_{y}Al_{1-y}N where y decreases in value within a range between 0.10 and 0.70 and has a thickness of between 40 and 500 angstroms; and
the increasing graded back barrier comprises In_{z}Al_{1-z}N where z increases in value within a range between 0.10 and 0.70 and has a thickness of between 40 and 500 angstroms.

6. The heterostructure of claim 1, wherein the ungraded back barrier comprises a lower ungraded back barrier and an upper ungraded back barrier.

7. The heterostructure of claim 6, wherein:
the lower ungraded back barrier comprises AlₓGa₁₋ₓN where x is between 0.10 and 0.40 and has a thickness of between 40 and 500 angstroms;
the upper ungraded back barrier comprises GaN and has a thickness of between 40 and angstroms; and
the graded back barrier comprises In_{y}Al_{1-y}N where y increases in value within a range between 0.10 and 0.70 and has a thickness of between 40 and 500 angstroms.

8. The heterostructure of claim 1, wherein the buffer comprises a dopant or crystal defects configured to provide a recombination pathway for the mobile charges.

9. The heterostructure of claim 1, further comprising:
a buffer contact coupled to the buffer, wherein the buffer contact is configured to provide an escape path for the mobile charges generated outside the channel.

10. A high-electron-mobility transistor (HEMT) comprising:
a substrate;
a radiation-tolerant Group III-Nitride heterostructure formed over the substrate, wherein the heterostructure comprises at least one upper layer and an ungraded/graded back barrier, wherein either a portion of the ungraded/graded back barrier is configured to function as a channel or the at least one upper layer comprises a channel, wherein the channel is configured to comprise an induced 2DEG, and wherein the ungraded/graded back barrier is configured to direct mobile charges generated outside the channel in a direction away from the channel and toward the substrate; and
a source contact, a drain contact, and a gate contact formed over the ungraded/graded back barrier.

11. The HEMT of claim 10, wherein:
the ungraded/graded back barrier comprises an ungraded back barrier formed over the substrate and a graded back barrier formed over the ungraded back barrier;
the ungraded back barrier comprises AlGaN; and
the graded back barrier comprises InAlN.

12. The HEMT of claim 11, wherein:
the ungraded back barrier comprises AlₓGa₁₋ₓN where x is between 0.10 and 0.40 and has a thickness of between 40 and 500 angstroms; and
the graded back barrier comprises In_{y}Al_{1-y}N where y decreases in value within a range between 0.10 and 0.70 and has a thickness of between 40 and 500 angstroms.

13. The HEMT of claim 11, wherein the graded back barrier comprises a double-graded back barrier.

14. The HEMT of claim 13, wherein:
the double-graded back barrier comprises a decreasing graded back barrier and an increasing graded back barrier;
the ungraded back barrier comprises AlₓGa₁₋ₓN where x is between 0.10 and 0.40 and has a thickness of between 40 and 500 angstroms;
the decreasing graded back barrier comprises In_{y}Al_{1-y}N where y decreases in value within a range between 0.10 and 0.70 and has a thickness of between 40 and 500 angstroms; and
the increasing graded back barrier comprises In_{z}Al_{1-z}N where z increases in value within a range between 0.10 and 0.70 and has a thickness of between 40 and 500 angstroms.

15. The HEMT of claim 11, wherein the ungraded back barrier comprises a lower ungraded back barrier and an upper ungraded back barrier.

16. The HEMT of claim 15, wherein:
the lower ungraded back barrier comprises AlₓGa₁₋ₓN where x is between 0.10 and 0.40 and has a thickness of between 40 and 500 angstroms;
the upper ungraded back barrier comprises GaN and has a thickness of between 40 and angstroms; and
the graded back barrier comprises In_{y}Al_{1-y}N where y increases in value within a range between 0.10 and 0.70 and has a thickness of between 40 and 500 angstroms.

17. The HEMT of claim 10, further comprising:
a substrate contact coupled to the substrate, wherein the substrate contact is configured to provide an escape path for the mobile charges generated outside the channel.

18. A method comprising:
forming a buffer;
forming an ungraded back barrier over the buffer;
forming a graded back barrier over the ungraded back barrier; and
forming at least one upper layer over the graded back barrier;
wherein either a portion of the graded back barrier is configured to function as a channel or the at least one upper layer comprises a channel;
wherein the channel is configured to comprise an induced 2DEG; and
wherein the ungraded back barrier and the graded back barrier are configured to direct mobile charges generated outside the channel in a direction away from the channel and toward the buffer.

19. The method of claim 18, wherein forming the graded back barrier over the ungraded back barrier comprises:
forming a decreasing graded back barrier over the ungraded back barrier; and
forming an increasing graded back barrier over the decreasing graded back barrier.

20. The method of claim 18, wherein forming the ungraded back barrier over the buffer comprises:
forming a lower ungraded back barrier over the buffer; and
forming an upper ungraded back barrier over the lower ungraded back barrier.
